(19) United States
(12) Patent Application Publication
(10) Pub. No.: US 2005/0090053 A1
(43) Pub. Date: Apr. 28, 2005

(54) Memory chip with low-temperature layers in the trench capacitor

(75) Inventors: Dietmar Temmler, Dresden (DE); Martin Gutsche, Dorfen (DE); Martin Popp, Dresden (DE); Harald Seidl, Poring (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/501,880

(22) PCT Filed: Jan. 8, 2003
(86) PCT No.: PCT/EP03/00088

(30) Foreign Application Priority Data
Jan. 21, 2002 (DE) 10202138.4
Apr. 18, 2002 (DE) 10217261.7

(51) Int. Cl. H01L 21/8242

(52) U.S. Cl. 438/243

(57) ABSTRACT

Memory cells having trench capacitors, the trench capacitor being at least partially filled with a material which could not withstand high-temperature processes used during the fabrication of a memory chip without impairment of its electrical parameters. What is essential to the invention is that the material of the trench capacitor is introduced into the trench after the high-temperature processes. The method according to the invention makes it possible to use dielectric layers having large dielectric constants and electrode layers made of metallic material. The electrical properties of the trench capacitor are thus improved in comparison with known trench capacitors.

### CLAIM FOR PRIORITY

This application is a national stage of International Application No. PCT/EP03/00088 which was filed on Jan. 8, 2003, and which claims the benefit of priority to German Application Nos. 102 02 138.4 and 102 17 261.7 filed Jan. 21, 2002 and Apr. 18, 2002, respectively.

### TECHNICAL FIELD OF THE INVENTION

The invention relates to a memory chip having a trench capacitor memory cell and to a method for fabricating a trench capacitor memory cell.

### BACKGROUND OF THE INVENTION

Memory chips are preferably fabricated by semiconductor technology and are provided with dynamic or static memory cells. A dynamic memory cell comprises a selection transistor and a storage capacitor. The memory states 0 and 1 correspond to a positive or a negative polarity of the storage capacitor. Since the capacitor charge is reduced in a time of approximately 1 second on account of recombination and leakage currents, the charge has to be repeatedly refreshed. The storage capacitor is formed as a trench capacitor, for example. The particular feature of the trench capacitor is that the capacitor is introduced in the form of a trench into a substrate. The selection transistor for driving the trench capacitor is arranged in the surface of the substrate (planar transistor) or in the upper section of the memory trench (vertical transistor).

Corresponding memory cells having trench capacitors are described in the published patent applications DE 19941147 and DE 199441148. In the case of the memory cells described, the storage capacitance is formed in the form of a trench sunk deep into the semiconductor substrate, while the remaining functional and wiring elements of the memory matrix and of the memory periphery are arranged above the trench without any disturbing topography on the planar substrate surface. This embodiment facilitates the patterning of the planes above the trench plane. By way of example, this arrangement permits a further-reaching scaling, i.e. a further miniaturization of the structures and an optional integration of memory and other functions on the chip without complicated, specific process adaptations.

An increase in the area-specific storage capacitance in the course of scaling has hitherto been realized by means of conventional expansion/extension of the following solutions: the thickness of the storage dielectric is reduced to below 5 nm. However, a further reduction of the thickness is limited to approximately 4 nm due to yield, leakage current and reliability problems.

The depth of the trench is increased to 7 μm, which corresponds to an aspect ratio of approximately 40. A high outlay for the fabrication of the etching hard mask and a long process time are thus currently unavoidable in the case of the industrially available etching installations. An increase in the trench aspect ratio of >60 does not appear to be feasible at the present time for series production.

A lateral widening of the trench is maximized right into the region of the trench bottom by means of proportionately isotropic etching (bottling). Experience shows that this measure can be implemented up to a distance between adjacent trench sidewalls of approximately 0.6 times the minimum feature size and is limited by process stability and homogeneity of the trench patterning.

The market-driven reduction of costs per memory unit compels further increasing of the memory size by increasing the integration density (memory cells/chip area). The associated scaling of the area and feature size of the memory cell and of the storage capacitor increasingly requires further measures for ensuring the minimum capacitance, which is approximately 35 to 40 fF in the case of trench capacitors.

Sense amplifiers, which are used to read out the information stored in the trench capacitor, require a sufficient signal level for reliably reading out the information held in the memory cell. The ratio of the storage capacitance to the capacitance of the bit line via which the stored information is passed to the sense amplifier is crucial in determining the signal level. If the storage capacitance is too low, then the information stored in the trench capacitor can no longer be unambiguously identified as a signal level by the sense amplifier on the bit line.

Since the stored charge additionally flows away via leakage currents, a smaller capacitance has the disadvantage that the charge has to be refreshed at shorter time intervals (higher refresh frequency). If a minimum quantity of charge of the storage capacitor is undershot on account of the leakage currents, then it is not possible for the sense amplifier to read out the stored information.

In memory cells having trench capacitors, hitherto use has been made exclusively of material combinations comprising thin silicon dioxide and silicon nitride (Si₃N₄) layers (NO, ON, ONO) as the storage dielectric and doped polysilicon layers as the electrode material. These materials are resistant to high temperatures and their properties are not adversely altered by the temperatures necessary for introducing a transistor after the fabrication of the trench capacitor.

### SUMMARY OF THE INVENTION

The invention provides a memory cell having a trench capacitor which has an increased storage capacitance in comparison with the trench capacitors used hitherto. Furthermore, the invention is to provide a method for fabricating a memory cell having a trench capacitor which has an increased storage capacitance in comparison with the trench capacitors known hitherto.

One advantage of the invention is that the trench is at least partially provided with a filling which is unstable at high temperatures usually employed during the fabrication of a transistor.

Preferably, the filling at least partially has a metallic material. The use of a metallic material as an electrode material reduces the resistance for making contact with the trench capacitor. The small resistance enables the signal to be reliably detected by a sense amplifier.

In a further advantageous embodiment, the filling at least partially has a dielectric material having a high dielectric constant. Dielectric materials having a high dielectric constant are usually stable up to temperatures of approximately 800° C. Therefore, the application of the dielectric materials having high dielectric constants in the fabrication of a memory cell in the form of a trench capacitor has not been possible hitherto. Since, however, in the embodiment of the memory cell according to the invention, the dielectric material is introduced into the trench after the high-temperature processes, it can thereby be used without problems in the trench memory cell. The use of a dielectric material having a high dielectric constant has the advantage that a larger quantity of charge can be stored with the area of the trench capacitor remaining the same, i.e. the storage capacitance of the trench capacitor is increased.

In a further preferred embodiment, both a metallic layer and a dielectric layer having a high dielectric constant are used. A particularly advantageous trench capacitor is obtained through the combination of the two advantageous materials. The metallic layer provides for a low resistance when making contact with the trench capacitor and the dielectric layer provides for a large charge capacitance of the trench capacitor.

Preferably, an electrically conductive layer is formed in a manner adjoining the trench in the substrate, which layer forms a counterelectrode of the capacitor. A particularly high storage capacitance is obtained on account of the arrangement of the electrically conductive layer near to the filling of the trench capacitor.

In a further preferred embodiment, the trench is covered by a covering layer having an opening for making electrical contact with the filling of the trench. A dielectric layer is at least partially applied on the underside of the covering layer. In this way, the area of the covering layer is also utilized for the storage of the charge. The capacitance of the trench capacitor is increased as a result.

The method according to the invention, in one embodiment, has an advantage that, after the fabrication of the trench, the trench is filled with an intermediate filling, that the transistor for driving the trench capacitor is subsequently introduced, that the intermediate filling is thereupon removed again from the trench and, finally, the dielectrically effective, final capacitor filling is introduced into the trench. The method according to the invention has the advantage that, during the process steps with high temperatures, the intermediate filling is introduced in the trench and the dielectric layer and/or an electrode layer are introduced into the trench only afterward. The intermediate filling is selected in such a way that it withstands high temperatures without significant impairment of its mechanical properties, that it does not adversely influence the trench, and that it can easily be removed again from the trench. After the integration of the transistor, the trench is at least partially filled with a capacitor filling. In this way, it is possible to use, as the capacitor filling, materials which enable an improved functioning of the memory cell but do not tolerate high temperatures without a reduction of their material quality.

Preferably, a dielectric material having a high dielectric constant is used as the capacitor filling. The storage capacitance of the trench capacitor is thus increased.

In another embodiment according to the invention, preferably, for making contact with the dielectric layer, a metallic conductive layer is introduced into the trench as an electrode. The use of the metallic layer is possible only because it is not introduced until after the high-temperature processes. The metallic layer has the advantage that a lower resistance for making contact with the trench capacitor is achieved.

Preferably, in order to remove the intermediate filling, a channel is etched in and the sidewalls of the channel are covered with a protective layer. The intermediate filling is subsequently etched out from the trench via the channel. A simple removal of the intermediate filling is possible in this way.

### BRIEF DESCRIPTION OF THE DRAWINGS

The invention is explained in more detail below with reference to the figures, in which:

FIG. 1 shows a cross section through a first memory chip with a first memory cell.

FIG. 2 shows a view of the first memory chip in FIG. 1.

FIG. 3 shows a method sequence for fabricating a first memory cell.

FIG. 4 shows a cross section through a memory chip with a second memory cell.

FIG. 5 shows a view of the second memory chip of FIG. 4.

FIG. 6 shows a method sequence for fabricating the memory cell of the second memory chip.

FIG. 7 shows a method sequence for fabricating a third memory cell.

### DETAILED DESCRIPTION OF THE INVENTION

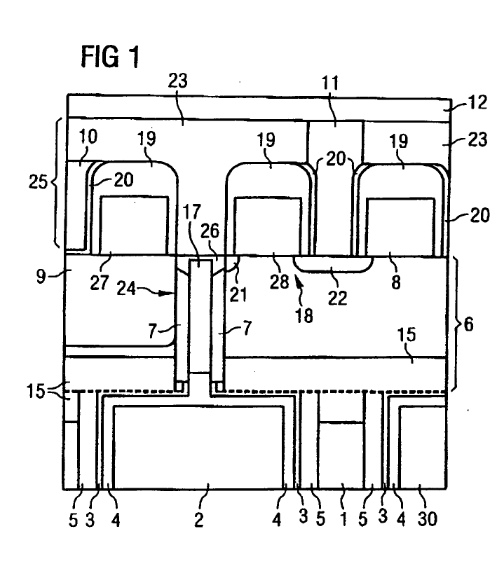

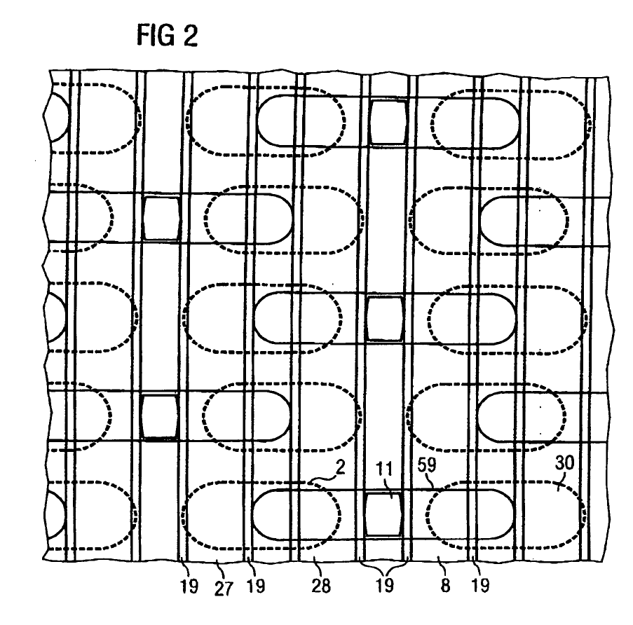

FIG. 1 shows part of a cross section through a memory chip formed in the form of a DRAM. The detail illustrates a memory cell comprising a transistor and a trench capacitor. The trench capacitor has a trench 2 introduced into a semiconductor substrate 1. The semiconductor substrate 1 is usually formed in the form of a silicon wafer. The trench 2 has a rectangular cross section, vertical plate doping zones 5 being introduced in the sidewalls which delimit the trench 2. The vertical plate doping zones 5 constitute first doping zones and are formed at the sidewalls of the trench 2. In the upper region of the trench 2, horizontal plate doping zones 15 are arranged in a manner adjoining the vertical plate doping zones 5 and constitute second doping zones which are essentially formed horizontally and are formed both laterally with respect to a vertical plate doping zone 5 and above the trench 2 in an epitaxial layer 6. The epitaxial layer 6 is essentially formed as an epitaxial silicon layer. The vertical and horizontal plate doping zones 5, 15 constitute a second electrode of the trench capacitor. A storage dielectric 3 is applied on the inner wall of the trench 2. The storage dielectric 3 preferably covers the entire wall of the trench 2. In the upper region, the trench 2 opens into a strap channel 24, which is preferably routed perpendicularly through the epitaxial layer 6 upward as far as an intermediate insulation layer 23. The strap channel 24 is laterally delimited by the epitaxial layer 6. Furthermore, an insulation collar 7 is arranged in the strap channel 24 at a predetermined distance from the lower edge of the strap channel 24. The insulation collar 7 is formed in sleeve-type fashion and reaches as far as a predetermined distance from the top side of the epitaxial layer 6. The storage dielectric 3 is also arranged on the underside of the epitaxial layer 6 above the trench 2 and preferably routed as far as the lower edge of the insulation collar 7. A trench electrode 4 is arranged on the inner side of the storage dielectric 3 and is likewise routed right into the strap channel 24. The trench electrode 4 constitutes an electrode of the trench capacitor. Preferably, the trench electrode 4 is routed upward in the strap channel 24 to above the lower edge of the insulation collar 7. A conductive strap filling 17 is arranged in the strap channel 24 and is routed upward to just below the upper edge of the covering layer 6. The strap filling 17 is surrounded by a strap cap 26, produced from a conductive material, in the upper end region. The strap cap 26 is formed in the form of a sleeve with an end plate and bears on the insulation collar 7 with a sleeve edge and on the strap filling 17 with the end plate. The strap cap 26 terminates approximately with the upper edge of the epitaxial layer 6.

The epitaxial layer 6 essentially comprises a silicon layer which is arranged above the trench 2 and in the lower region of which the horizontal plate doping zone 15 is arranged. The horizontal plate doping zone 15 adjoins both the strap channel 24 laterally and the vertical plate doping zone 5. In the left-hand region beside the strap channel 24, the epitaxial layer 6 has an STI field insulation layer 9 that is routed as far as the upper edge of the epitaxial layer 6. A drain region 21 is formed in a manner adjoining the strap cap 26 in the right-hand region beside the insulation collar 7. A source region 22 is arranged at a predetermined lateral distance to the right thereof in a manner adjoining the upper edge of the epitaxial layer 6.

In a third layer 25, a passive word line 27 is arranged in a manner adjoining the field insulation layer 9 and is covered by a word line covering insulation 19. The word line covering insulation 19 is covered by a sealing layer 20 on the left-hand side, a first insulation filling 10 being applied in turn on said sealing layer. At a predetermined distance from the passive word line 27, an active first word line 28 is arranged on the right beside the strap channel 24 in the third layer 25. The first active word line 28 bears on an oxide layer arranged on the epitaxial layer 6. In two opposite edge regions, the first active word line 28 is arranged above the drain region 21 and the source region 22. The first word line 28, the drain and source regions 21, 22 and the region of the epitaxial layer 6 which is arranged under the first active word line constitute a transistor 18.

A further active word line 8 is arranged in the third layer 25 on the right beside the first active word line 28 at a predetermined distance. The further active word line 8 is isolated from the epitaxial layer 6 by an oxide layer and arranged with a left-hand edge region above the source region 22. The first and the further word line 28, 8 are in each case covered by a word line covering insulation 19. The word line covering insulation 19 is in turn covered with a sealing layer 20 in the lateral edge region, the sealing layer being routed from the upper end region of the word line covering insulation 19 as far as the upper edge of the covering layer 6. Between the first and further word lines 28, 8, a bit line plug 11 is arranged above the source region 22 in the third layer 25, which is routed as far as the upper edge of the third layer 25. The bit line plug 11 constitutes a contact terminal. The further regions of the third layer 25 are filled by the intermediate insulation 23. A bit line 12 is applied on the third layer 25. The bit line 12 is in conductive contact with the bit line plug 11.

The memory cell of FIG. 1 functions as follows: a charge is stored in the trench capacitor formed by the storage dielectric 3, the trench electrode 4 and the vertical and horizontal plate doping zones 5, 15. If the charge is intended to be read out, then a predetermined voltage is applied to the first word line 28, so that the transistor 18 comprising the first word line 28, the drain region 21 and the source region 22 is switched in electrically conductive fashion. Since the drain region 21 is electrically conductively connected to the trench electrode 4 via the strap cap 26 and the conductive strap filling 17, the electrical charge stored in the trench capacitor is transferred onto the bit line 12 via the transistor 18 and the bit line plug 11. The bit line 12 is usually connected to a sense amplifier which, on the basis of the charge stored in the trench capacitor, detects and forwards the voltage level on the bit line 12. The formation of the trench electrode 4 in the form of a metallic material considerably reduces the nonreactive resistance for making contact with the trench capacitor.

Furthermore, the formation of the storage dielectric 3 in the form of a dielectric material having a high dielectric constant affords the advantage that a larger quantity of charge can be stored with the same dimensions in the trench capacitor. On account of the fabrication method according to the invention, the dielectric material used for the storage dielectric may be a material which is stable only up to a relatively low maximum temperature of, for example, 800 to 1050° C. Binary oxides such as e.g. tantalum oxide (Ta₂O₅) having a dielectric constant of 25 to 26 and a temperature stability of 800° C. are used as preferred materials. Furthermore, the use of aluminum oxide (Al₂O₃) having a dielectric constant of 10 and a temperature stability of up to 830° C. as storage dielectric 3 is advantageous.

As a further material, hafnium oxide (HfO₂) having a dielectric constant of 15 to 40 is preferably used as storage dielectric 3. Furthermore, zirconium oxide (ZrO₂) having a dielectric constant of 11 to 25 is taken into consideration. Moreover, lanthanum oxide (La₂O₃) having a dielectric constant of 20 to 30 may also be used as storage dielectric 3. When using lanthanum oxide, however, it should be taken into account that lanthanum oxide does not have ensured stability with respect to hydrogen. Moreover, yttrium oxide (Y₂O₃) having a dielectric constant of 12 to 15 may also be used for forming the storage dielectric 3.

Furthermore, aluminum oxide compounds are also appropriate for formation as the storage dielectric 3. The compounds with hafnium, zirconium and lanthanum are particularly suitable for the formation of the storage dielectric 3. By way of example, it is possible to use the material compounds Hf—Al—O, Zr—Al—O, La—Al—O.

Furthermore, the storage dielectric 3 may also be fabricated from silicate compounds such as e.g. Hf—Si—O, Zr—Si—O, La—Si—O or Y—Si—O. The material compound Hf₇Si₂₉O₆₄ having a temperature stability of up to 1050° C. is preferably used. The material compound Zr₄Si₃₁O₆₅ is also stable up to a temperature of 800° C. Moreover, a 30% strength lanthanum oxide-silicon oxide compound is suitable. Equally, a 70% strength silicon oxide-silicon-oxygen compound is stable up to a temperature of 1000° C. and suitable as the storage dielectric 3. A 30% strength hafnium oxide-silicon-oxygen compound and a 70% strength silicon oxide-silicon-oxygen compound is also suitable as the storage dielectric 3 and stable up to a temperature of 1000° C. Lanthanum dioxide silicate and silicon dioxide silicate have a dielectric constant of 14. Hafnium dioxide silicate and silicon dioxide silicate have a dielectric constant of 7.

Further material compounds which are suitable as dielectric material for the storage dielectric 3 are, by way of example, Y₂O₃—ZrO₂ having a dielectric constant of 30 and strontium titanium oxide (SrTiO₃) having a dielectric constant of 175. Strontium titanium oxide is stable up to a temperature of 800° C.

The trench electrode 4 is preferably fabricated from doped polysilicon or from a metal compound. On account of the method according to the invention, the storage dielectric 3 and/or the trench electrode 4 are introduced into the trench 2 after the process steps which require a high temperature. These are for example the processes for integration of the transistor. After the introduction of the storage dielectric layer 3 and the trench electrode layer 4, process steps with lower temperatures are carried out, which do not damage the temperature-sensitive dielectric and metallic materials of the storage dielectric 3 and the trench electrode 4.

FIG. 2 shows a view of the memory chip of FIG. 1 from above, various regions of the memory cell being depicted diagrammatically. The illustration shows a passive word line 27 covered with the word line covering insulation 19. The active first word line 28 is arranged beside the passive word line 27, and is likewise covered by a word line covering insulation 19. The form of the trench 2 is indicated in the form of a broken line. An active region 59, which is formed in the epitaxial layer 6 and extends over two trenches 2, 30, is indicated in the form of a solid line. The active region 59 identifies a region of the epitaxial layer 6 which is arranged between two trenches 2, 30 arranged next to one another and in which are formed two transistors with the first and the further word line 28, 8 as control terminals. The bit line plug 11 is depicted beside the first active word line 28. The second active word line 8 is arranged on the right beside the bit line plug 11, and is likewise covered by a word line covering insulation 19. The first and further word lines 28, 8 are arranged parallel to one another. The bit lines 12 arranged perpendicular to the word lines are not illustrated in FIG. 2. The further word line 8 is partially arranged above a further trench 30, which is likewise indicated in the form of a broken line. The connection of the further trench 30 to a further transistor, which is formed by the second word line 8, is formed in accordance with the connection of the trench 2 to the first word line 28.

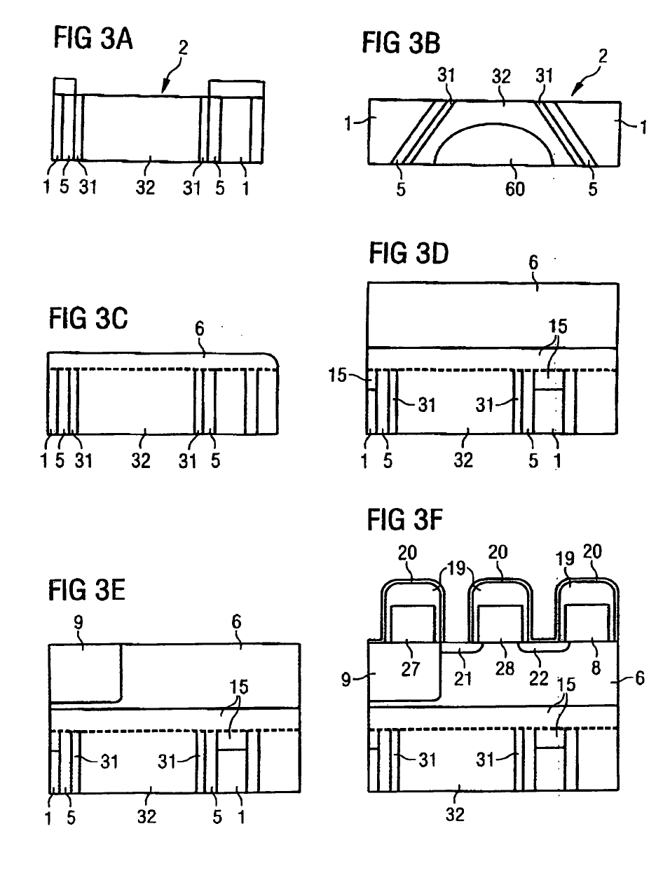

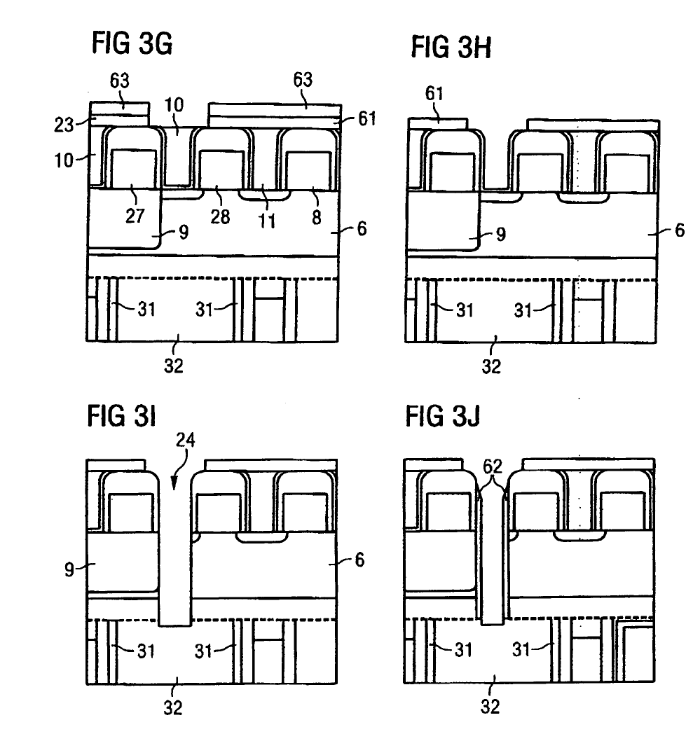

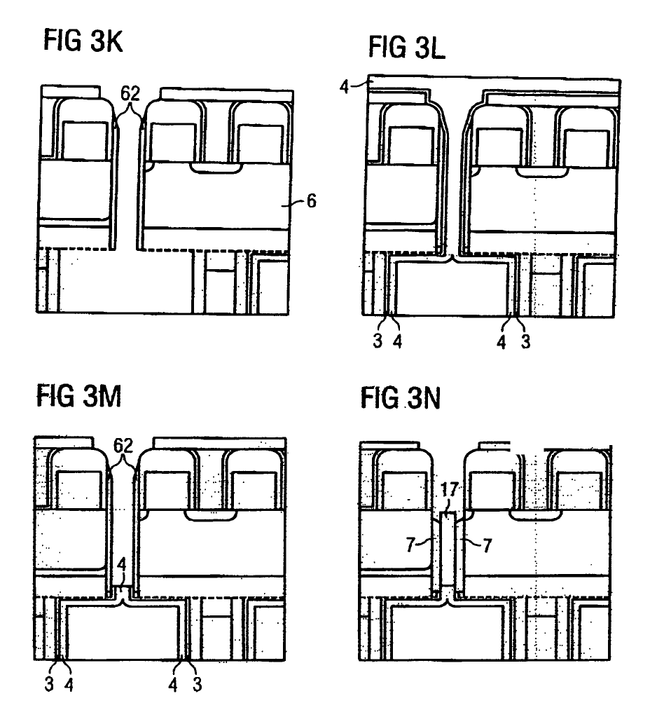

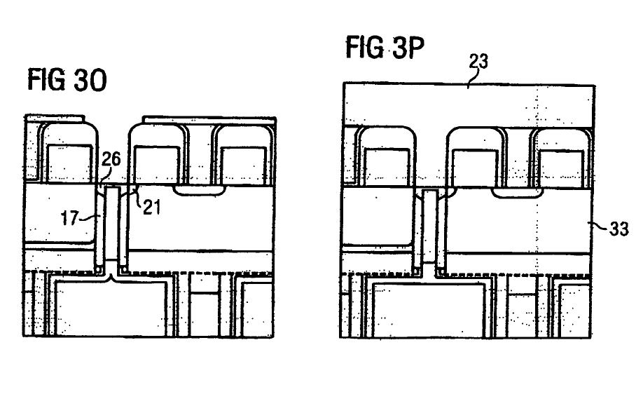

FIG. 3 shows the essential process steps for fabricating the memory cell according to the invention from FIG. 1. In this case, a trench 2 is etched into a, for example p-conducting, silicon substrate 1 by means of lithography and etching methods using a hard mask. For this purpose, the silicon substrate 1 is coated with a silicon dioxide layer and a silicon nitride layer as a hard mask. After the removal of the mask and cleaning, the vertical plate doping zone 5 is produced in the sidewalls of the trench 2 e.g. by means of an arsenic-doped glass layer 31 and subsequent diffusion process. Afterward, a dummy filling 32 is deposited until the trench 2 is completely filled. The dummy filling 32 is preferably formed from silicon dioxide and optimized for high wet etching rates.

In a first refinement of the method, the trench 2 is etched slightly bulgingly in the upper section by means of a proportional isotropic etching method, thereby producing a negative sidewall angle. As a result, the cross section of the trench opening increases downwardly. By virtue of the bulging form in the upper region of the trench 2, the trench 2 is closed by the dummy filling 32 actually before deeper sections of the trench 2 have been completely filled. As a result, an extended shrink hole, i.e. a cavity, which makes it significantly easier for the dummy filling 32 subsequently to be stripped out without any residues, remains in the lower region of the trench 2 along the axis of symmetry thereof. This effect may also be intensified by means of a nonconformal deposition method with deposition rates of the silicon oxide deposited onto the glass layer 31 that decrease greatly in the depth of the trench. FIG. 3B shows the arrangement of a filled trench 2 with a shrink hole 60.

In a further refinement of the method, instead of the silicon oxide, firstly a silicon layer is deposited onto the glass layer 31. The silicon layer is then etched back in planar fashion to just below the level of the surface of the silicon substrate 1. Afterward, firstly a silicon dioxide layer is deposited. Consequently, in this exemplary embodiment, the dummy filling comprises the glass layer 31 and an intermediate filling formed as a silicon layer, which is covered by a silicon oxide.

Afterward, the dummy filling 32 is etched back to the level of the surface of the silicon substrate 1 by means of a planar etching-back method. This method state is illustrated in FIG. 3A.

Afterward, the nitride layer and the oxide layer are removed and a monocrystalline silicon layer is formed with homogenous thickness as an epitaxial layer 6 on the open region of the silicon substrate 1 and over the trench 2 provided with the dummy filling. This method state is illustrated in FIG. 3C. A selective epitaxial deposition method, described in greater detail in the published patent application DE 19941148, is preferably used for depositing the silicon layer.

In a subsequent method step, the horizontal plate doping zone 15 is introduced into the epitaxial layer by means of an ion implantation, the plate doping zone being n-doped. This method state is illustrated in FIG. 3D. Afterward, an STI field insulation layer 9 is introduced into the epitaxial layer 6 over a left-hand partial region of the trench 2. This method state is illustrated in FIG. 3E. The field insulation layer 9 reaches as far as a predetermined distance from the horizontal plate doping zone 15 and is routed up to the upper boundary of the epitaxial layer 6. The field insulation layer 9 extends laterally over part of the trench 2.

Afterward, a passive word line 27 and a first and further active word line 28, 8 are applied to the epitaxial layer 6. The word lines are covered with word line covering insulation layers 19. Afterward, the drain region 21 and the source region 22 are introduced into the epitaxial layer 6 according to known methods, as described for example in DE 19941148. The drain and source regions 21, 22 are introduced according to known doping methods and a subsequent high-temperature diffusion phase. In addition, a sealing layer 20 is applied to the word line covering insulation layer 19. The drain region 21, the source region 22 and the first active word line 28 form a first transistor 18. This method state is illustrated in FIG. 3F.

In a subsequent method step, a first insulation filling 10 is introduced between the passive word line 27 and the first active word line 28. Moreover, a conductive bit line plug 11 is introduced between the first and second active word lines 28, 8. The first insulation filling 10 and the bit line plug 11 are etched away down to the upper edge of the sealing layer 20. The bit line plug 11 is thereupon subjected to an annealing process. This process essentially constitutes the last high-temperature loading. Afterward, a strap window mask 61 comprising Si₃N₄ and a strap window hard mask 63 comprising SiO₂ are applied to the substrate. Over the intermediate region between the passive word line 27 and the active word line 28, a contact window is introduced into the strap window mask and the strap window hard mask 61, 63. This method state is illustrated in FIG. 3G. Afterward, the region between the passive word line 27 and the first active word line 28 is etched free and the first insulation filling 10 is removed between the first active and the passive word line. Moreover, the strap window hard mask 63 is removed. This method state is illustrated in FIG. 3H.

Afterward, a strap channel 24 is etched through the covering layer 6 as far as the upper edge of the filled trench 2. This method state is illustrated in FIG. 3I.

In the subsequent process step, the sidewall of the strap channel 24 is covered with a thin etching channel protective layer 62. The etching channel protective layer 62 is formed as a nitride layer and routed as far as the upper edge of the dummy filling 32. This method state is illustrated in FIG. 3J.

Afterward, the etching channel protective layer 62 is removed again from the surface of the dummy filling by means of an anisotropic selective plasma etching.

During a subsequent process step, the dummy filling and the glass layer are removed from the trench 2 by means of an isotropic etching operation without any residues by virtue of the spacing which is arranged between active and passive word lines 27, 28 and is necessary for the later strap terminal temporarily being utilized as a sealed etching channel. During this process step, all the surfaces that are otherwise open on the memory chip are made to be resistant to the etching solution used for stripping out the intermediate filling or are covered by a sealing layer. This method state is illustrated in FIG. 3K.

The cleaning of the inner wall of the trench 2 is followed preferably by a conformal deposition of the storage dielectric 3 and then a deposition of the trench electrode layer 4. The storage dielectric 3 and the trench electrode 4 are preferably deposited according to an atomic layer deposition method (ALD). This method state is illustrated in FIG. 3L. FIG. 3L reveals that the material forming the trench electrode 4 also fills the strap channel 24.

Afterward, the trench electrode layer 4 is etched back selectively to just above the upper edge of the trench 2. The etched-back trench electrode layer 4 is then used as an etching mask for the isotropic removal of the uncovered regions of the storage dielectric 3. In this case, the etching channel protective layer 62 is used as an etching mask in this process. The method state is illustrated in FIG. 3M.

In an advantageous refinement of the method according to the invention, the trench electrode 4 is selectively etched back to just below the upper edge of the trench 2, as a result of which the trench 2 is opened again. The trench electrode 4 is then deposited again, thereby advantageously increasing the thickness of the trench electrode 4 in the trench 2. This process cycle of deposition and etching-back of the trench electrode 4 can be carried out repeatedly as required. In this case, however, the last deposited trench electrode layer 4 has to be etched back to just above the upper edge of the trench, as is illustrated in FIG. 3M. A larger thickness of the trench electrode 4 in the upper region of the trench 2 has a particularly low ohmic resistance for making contact with the trench electrode 4 situated in the trench 2. Consequently, this embodiment is particularly advantageous for making contact with the trench capacitor with a low ohmic resistance.

The strap filling 17 is subsequently formed, the strap filling being surrounded by an insulation collar 7. For this purpose, firstly the etching channel layer 62 is etched away to just below the upper edge of the trench electrode 4 and then the sidewalls of the strap channel 24 are provided with an insulation collar 7. The insulation collar 7 preferably comprises silicon dioxide. The electrically conductive strap filling 17 is subsequently introduced into the insulation collar 7. This method state is illustrated in FIG. 3N.

Afterward, the upper region of the insulation collar 7 is etched away and a strap cap 26 made of an electrically conductive material is applied to the strap filling 17 and the insulation collar 7. The strap cap 26 is conductively connected to the strap filling 17 and to the drain terminal 21. This method state is illustrated in FIG. 3O.

Afterward, the still open region between the passive word line 27 and the first active word line 28 is filled with an intermediate insulation 23 and the surface of the word lines is thus covered. This method state is illustrated in FIG. 3P. A connecting hole is etched into the intermediate insulation layer 23 over the bit line plug 11, and the connecting hole is filled in planar fashion with a conductive layer. The bit line 12 is subsequently applied to the second intermediate insulation layer 23. A memory chip having memory cells in accordance with FIG. 1 is obtained in this way.

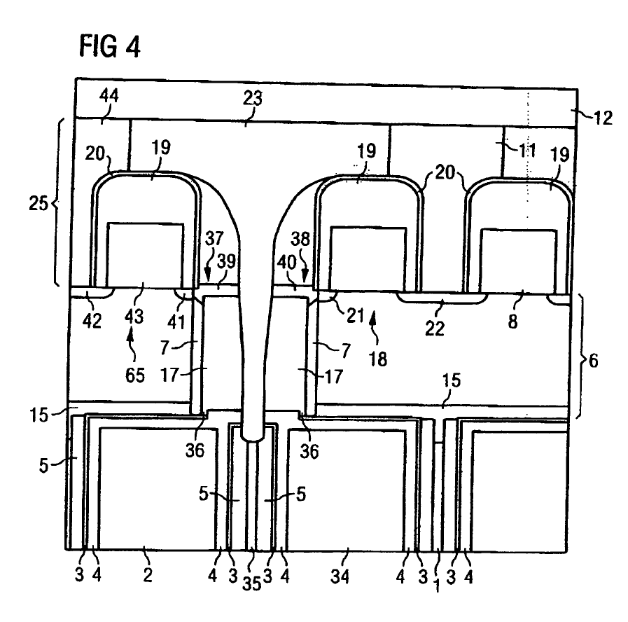

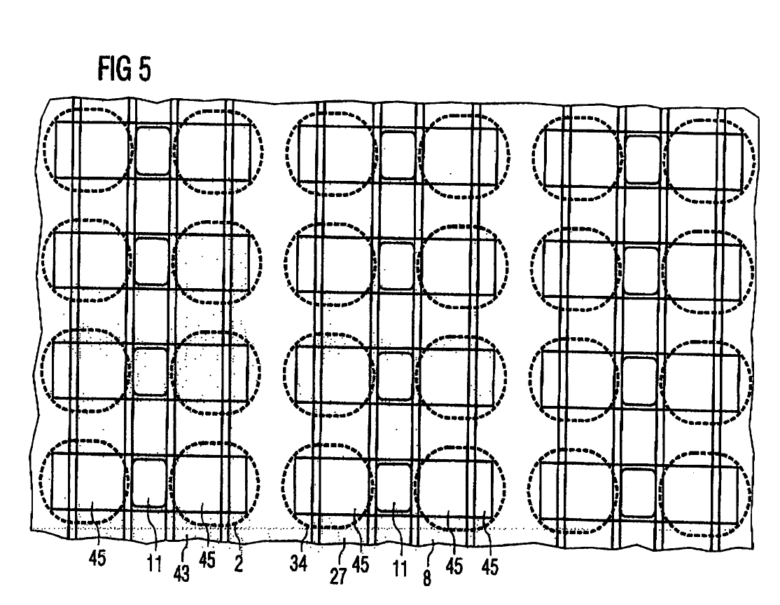

FIG. 4 shows a further embodiment of a memory cell in the form of a sub-8F² DRAM cell with an open bit line layout with a buried trench capacitance connected in a self-aligned manner with a low-temperature high-K dielectric and a metallic electrode. The construction of the trench capacitor is essentially identical to the construction of the trench capacitor of FIG. 1. One essential difference is that two adjacent trenches 2, 34 are electrically contact-connected via two strap contacts 37, 38, the strap contacts 37, 38 being arranged next to one another. FIG. 4 shows a cross section through a DRAM memory with a first and a second trench 2, 34 introduced into a semiconductor substrate 1. The first and second trenches 2, 34 are in each case surrounded by a vertical plate doping zone 5, which are introduced into the semiconductor substrate 1 at the sidewalls of the trench 2. Furthermore, the sidewalls of the first and second trenches 2, 34 are covered with a storage dielectric 3. A trench electrode 4 is applied on the storage dielectric 3. The interior space of the first and second trenches 2, 34 is partially formed as cavity.

The semiconductor substrate 1 is formed in the form of a separating web 35 between the mutually assigned vertical plate doping zones 5 of the first and second trenches 2, 34. The first and second trenches 2, 34 are covered with an epitaxial layer 6. The epitaxial layer 6 preferably comprises an epitaxial silicon layer. A common connecting channel 36 is introduced into the epitaxial layer 6, said connecting channel being arranged symmetrically with respect to the separating web 35 and being arranged in each case over part of the first and second trenches 2, 34. The common connecting channel 36 is surrounded by an insulation collar 7 and is thus electrically insulated from the surrounding silicon layer. The insulation collar 7 comprises silicon dioxide, for example. In the lower region, the epitaxial layer 6 has a horizontal plate doping zone 15 adjoining the insulation collar 7. An intermediate insulation 23 is introduced symmetrically in the common connecting channel 36, and, proceeding from a region above a third word line 43 and the first active word line 28, is routed between the third and first word lines 43, 28 downward through the common connecting channel 36 as far as the separating web 35. The intermediate insulation 23 constitutes an insulation filling and leads to a division of the common connecting channel 36 into the first and second strap contacts 37, 38, which are electrically insulated from one another. The first and second strap contacts 37, 38 are in each case filled with an electrically conductive strap filling 17. The strap filling 17 is routed as far as a predetermined distance from the upper edge of the epitaxial layer 6. A first and a second strap cap 39, 40 are applied on the strap filling 17 of the first and second strap contacts 37, 38, the strap caps projecting somewhat beyond the upper boundary of the epitaxial layer 6. The first and second strap caps 39, 40 are fabricated from an electrically conductive material, preferably from doped silicon. In the region of the first and second strap cap 39, 40, the insulation collar 7 is at a predetermined distance from the upper edge of the epitaxial layer 6. In this way, a conductive connection is formed between the first or second strap cap 39, 40 and a drain region 21 or a further drain region 41, which are introduced into the epitaxial layer 6 in a manner adjoining the first and second strap caps 39, 40. The further drain region 41 is formed in a manner adjoining the third word line 43.

At the underside of the strap fillings 17 of the first and second strap contacts 37, 38, the epitaxial layer 3 is arranged in an edge region in a manner adjoining the insulation collar 7. The adjacent trench electrodes 4 adjoin the strap fillings 17 in the direction of the intermediate insulation 23. In this way, an electrically conductive contact is produced between the trench electrode 4 in the respective trench and the drain region 21 or the further drain region 41. In the epitaxial layer 6, a source region 22 and a further source region 42 are introduced in the upper boundary region beside the drain region and the further drain region 41, and are at a predetermined distance from the drain region 21 and the further drain region 41. In the region between the drain region 21 and the source region 22, a first word line 28 is applied on the epitaxial layer 6, which is surrounded by a word line covering insulation 19. A sealing layer 20 is in turn applied on the word line covering insulation 19. The drain terminal 21, the source terminal 22 and the first word line 28 form the first transistor 18. A second word line 8 is arranged at a predetermined distance from the first word line 28, and is in turn surrounded with a word line covering insulation 19 and a sealing layer 20 applied thereto. A bit line plug 11 is introduced in the region between the first and second word lines 28, 8, and, proceeding from the first source region 22, is routed through the third layer 25 as far as a bit line 12. Through the bit line plug 11, an electrically conductive connection is produced between the bit line 12 and the first source region 22.

In the region between the further drain region 41 and the further source region 42, the third word line 43 is applied on the epitaxial layer 6, and is covered by a word line covering insulation 19 and a sealing layer 20. The third word line 43 together with the further drain region 41 and the further source region 42 constitute a second transistor 65. Arranged over the further source region 42 is a second bit line plug 44, which is routed through the third layer 25 as far as the bit line 12, applied on the third layer 25. Via the second bit line plug 44, an electrically conductive connection is produced between the further source region 42 and the bit line 12. The first and second bit line plugs 11, 44 are electrically insulated from one another by the intermediate insulation layer 23. The intermediate insulation layer 23 is applied on the sealing layer 20, and on the first and third word lines 28, 43. The intermediate insulation layer 23 tapers in the direction of the separating web 35 proceeding from the upper edge of the sealing layer 20 of the first and third word lines 28, 43. The interspace between the tapered region of the intermediate insulation layer 23 and the lateral areas of the sealing layer 20 of the first and third word lines 28, 43 is filled by an intermediate layer which constitutes a strap isolating mask, is formed in electrically insulating fashion and adjoins the upper edge of the first and second strap caps 39, 40.

Via the bit line 12, as a result of the driving of the first word line 28, it is possible to produce an electrically conductive connection to the trench capacitor of the second trench 34 and to read out the information stored in the trench capacitor of the second trench. The information stored in the trench capacitor of the second trench 34 is read out via the second strap contact 38, the first drain region 21, the first source region 22 and the first bit line plug 11. Furthermore, as a result of a driving of the third word line 43, the information stored in the trench capacitor of the first trench 2 can be read out via the first strap contact 37, the further drain region 41, the further source region 42 and the second bit line plug 44 to the bit line 12.

The storage dielectric 3 is applied not only on the sidewalls of the first and second trenches 2, 34, but also on the underside of the epitaxial layer 6 which covers the first and second trenches 2, 34. Consequently, an enlarged area is provided for storing charges.

FIG. 5 shows a diagrammatic arrangement of the memory chip of FIG. 4 from above, the trenches 2, 34 being indicated by a broken line and the bit line plug 11 and an active zone 45 being indicated in the form of a solid line. Furthermore, the first, second and third word lines 28, 8, 43 are illustrated in the form of strips. The active zone 45 is formed in the epitaxial layer below two word lines 27, 8, which are jointly connected to a source region 22.

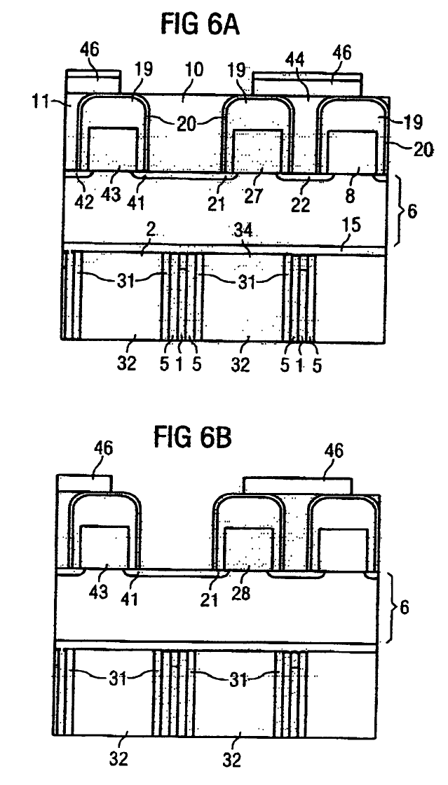

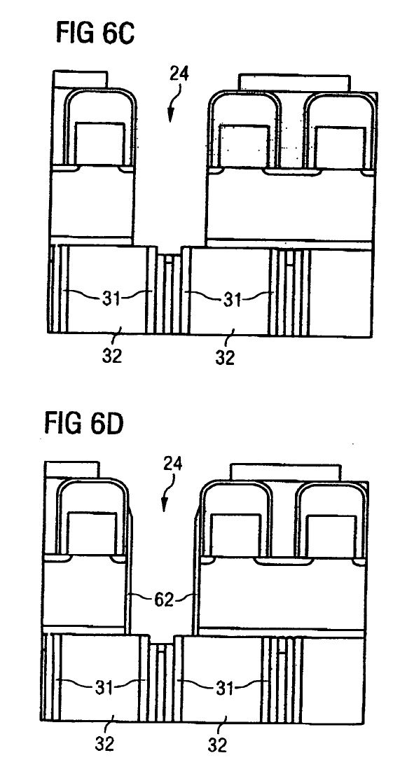

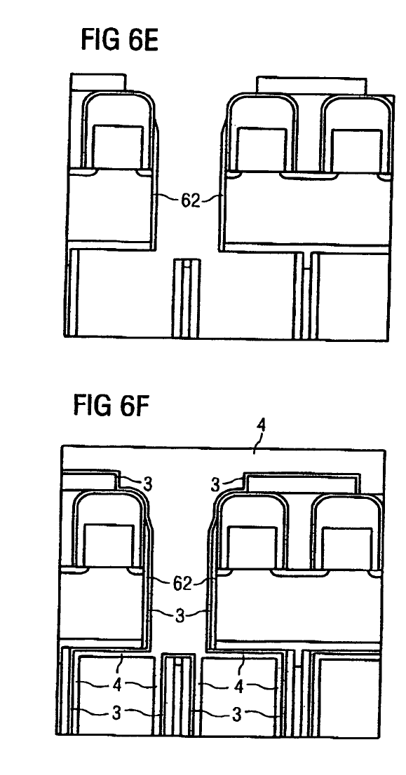

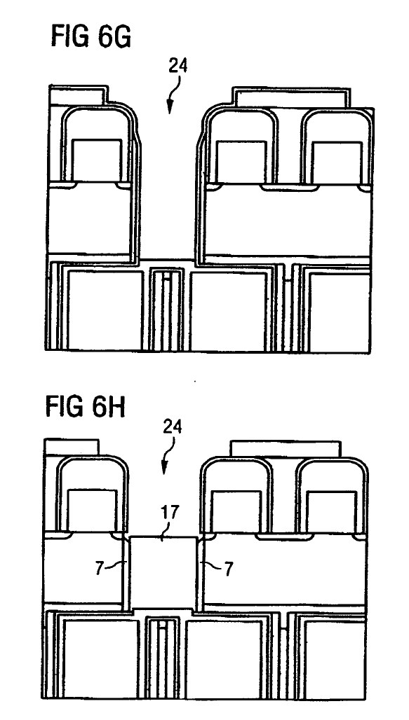

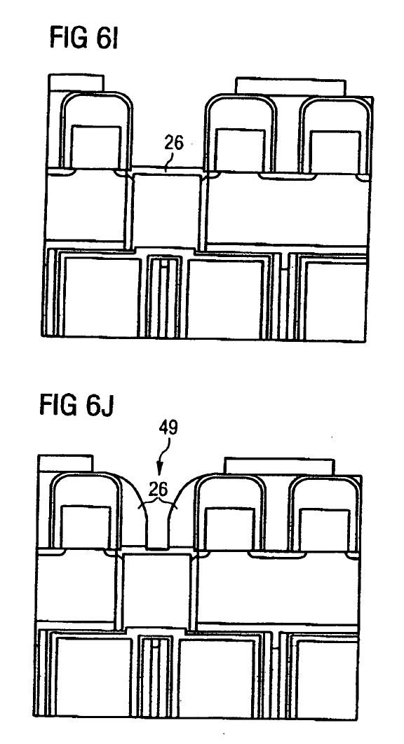

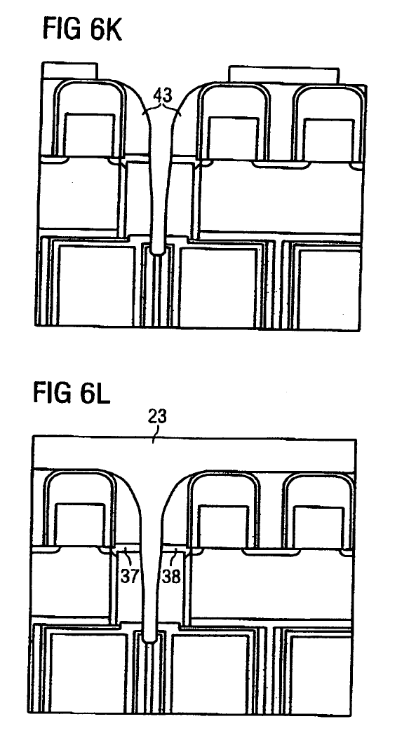

FIG. 6 shows the most important process steps for fabricating a memory chip in accordance with FIG. 4. The memory cell arrangement is fabricated by trenches 2, 34 firstly being etched into a p-conducting silicon substrate 1 coated with silicon oxide and silicon nitride by means of lithography and etching methods using a hard mask. After the removal of the mask and cleaning, an arsenic-doped glass layer 31 is applied to the sidewalls of the trenches 2, 34. A vertical plate doping zone 5 is produced in the sidewalls of the trenches 2, 34 by means of a subsequent diffusion operation. Afterward, the trenches 2, 34 are completely filled with an SiO₂ layer as a dummy filling 32.

In a first refinement of the method, the trenches 2, 34 are etched slightly bulgingly in the upper section by means of a proportionately isotropic etching, so that a negative sidewall angle is produced analogously to FIG. 3B. By virtue of the bulging form of the trench 2, 34, the opening of the trench 2, 34 is closed by the dummy filling before deeper sections of the trenches 2, 34 have been completely filled. As a result, an extended shrink hole, i.e. a cavity, remains in the lower region of the trenches 2, 34 along the axis of symmetry thereof. The cavity makes it significantly easier for the dummy filling subsequently to be removed without any residues. This effect may also be intensified by means of a nonconformal deposition of the dummy filling during which a greatly decreasing deposition rate is produced depending on the depth of the trench 2.

In a further refinement of the method, firstly a silicon layer is deposited instead of the dummy filling 32, the silicon layer is subsequently etched back in planar fashion to just below the level of the surface of the silicon substrate 1, and then an SiO₂ layer is deposited as a dummy filling 32.

In a subsequent method step, the dummy filling 32 is etched back to the level of the surface of the silicon substrate 1 by a planar etching-back method, then the silicon nitride and silicon oxide layers are removed, and a monocrystalline silicon layer is applied with homogeneous thickness as the epitaxial layer 6 to the surface of the silicon substrate 1 and to the dummy filling. The method for selective epitaxial deposition as described in the published patent application DE 19941148 is preferably used in this case.

The horizontal plate doping zone 15 is subsequently introduced in the epitaxial layer 6 by means of ion implantation. A strip-type STI field insulation layer 9 is then fabricated. The first, second and third word lines 28, 8, 43 are then introduced in the regions between the drain and source regions. The word lines are provided with a word line covering insulation 19 and a sealing layer 20. The doping regions of the transistors with the drain region 21, the source region 22, the further drain region 41 and the further source region 42 are then fabricated preferably in accordance with the method described in the published patent application DE 19941148. A first insulation filling 10 is subsequently introduced between the word lines. The first insulation filling 10 is removed in the region between the word lines which adjoin a common source region 22 and a first and second bit line plug 11, 44 are introduced. The bit line plugs 11, 44 are subsequently planarized back as far as the level of the upper edge of the sealing layer 20 of the word lines 28, 8, 43. Within these process steps, the bit line contacts are also annealed, which constitutes a last significant high-temperature loading of the entire process.

A strap isolating mask 46 is subsequently applied, which, as a contact window, keeps free the region between the first and third word lines 28, 43. This process status is illustrated in FIG. 6A. The drain region 21 and the further drain region 41 are still formed in contiguous fashion in this process status.

During the subsequent method step, the insulation filling 10 is completely removed by means of an etching method. This method state is illustrated in FIG. 6B. Afterward, an etching operation is performed to etch away the region arranged between the first and third word lines 28, 43 over the doping zones 21, 41 and the underlying epitaxial layer 6. Furthermore, part of a separating web 35 which is arranged between the first and second trenches 2, 34 and is formed by part of the substrate 1, and the adjoining vertical plate doping zones 5 are etched away. This produces a strap channel 24 to the dummy fillings 32 of the first and second trenches 2, 34. This method state is illustrated in FIG. 6C.

Afterward, the walls of the strap channel 24 are covered by an etching channel protective layer 62 made of nitride. In the region of the intermediate filling, the etching channel protective layer 62 is removed again by means of an anisotropic selective plasma etching method. This method state is illustrated in FIG. 6D. The dummy filling 32 and the glass layer 31 are then removed from the first and second trenches 2, 34 by means of an isotropic etching method without any residues. In this case, the region between the word lines is advantageously temporarily utilized as a sealed etching channel. This method state is illustrated in FIG. 6E. During this process step, all surfaces that are otherwise uncovered on the memory chip are made to be resistant to the etching solution used for stripping out the dummy filling or are covered by a sealing layer.

The cleaning of the inner walls of the first and second trenches 2, 34 is followed by a preferably conformal deposition of the storage dielectric 3. The trench electrode 4 is applied to the storage dielectric 3. Preferably, the storage dielectric 3 and the trench electrode 4 are applied by means of an atomic layer deposition method (ALD). In this case, the strap channel 24 and the surface of the memory chip with the storage dielectric 3 are covered by the trench electrode layer 4. This method state is illustrated in FIG. 6F.

Afterward, the trench electrode layer 4 is etched back to just above the upper edge of the first and second trenches 2, 34 by means of a selective etching-back method. The etched-back trench electrode layer 4 is thereupon used as an etching mask in order to remove regions of the storage dielectric 3 and of the etching channel protective layer 62 that are uncovered by means of an isotropic etching method. This method state is illustrated in FIG. 6G.

In an advantageous refinement of the method, the trench electrode layer 4 is selectively etched back to just below the upper edge of the first and second trenches 2, 34. In this way, the cavity of the first and second trenches 2, 34 is opened again. A further trench electrode layer 4 is subsequently deposited, thereby advantageously increasing the thickness of the resulting trench electrode layer 4 in the first and second trenches 2, 34. This process cycle of deposition and etching-back of the trench electrode layer 4 can be carried out repeatedly as required, the trench electrode layer 4 deposited last being etched back again to just above the upper edge of the first and second trenches 2, 34.

In a further method step, the insulation collar 7 is introduced in the region of the covering layer 6 in the strap channel 24 and the insulation collar 7 is subsequently filled with a conductive strap filling 17. The strap filling 17 is subsequently etched back a predetermined amount. The insulation collar 7 is then etched back in the upper region, the etched-back strap filling 17 serving as an etching mask. This method state is illustrated in FIG. 6H.

Afterward, a strap cap 26 is applied to the insulation collar 7 and the strap filling 17. The strap cap 26 is filled up to a predetermined distance above the upper boundary of the covering layer 6 and comprises an electrically conductive material. This method state is illustrated in FIG. 6I.

In a further process step, a strap isolating mask 46 is introduced into the strap channel 24, and covers the sidewalls of the sealing layers 20 of the first and third word lines 28, 43. The strap isolating mask 46 is preferably formed from Si₃N₄ and defines an etching channel 49 which is routed as far as the strap cap 26. This method state is illustrated in FIG. 6J.

Afterward, in an etching process, the etching channel 49 is etched in further through the strap cap 26, the strap filling 17, the trench electrode 4, the storage dielectric 3 right into the upper end of the separating web 35 and into the laterally adjoining vertical plate doping zones 5. This method state is illustrated in FIG. 6K.

Afterward, the intermediate insulation layer 23 is introduced into the etching channel 49 and the first and second strap contacts 37, 38 are created in this way. This method state is illustrated in FIG. 6L. The further process steps for fabricating the bit line contact, for applying the bit line 12 and subsequent metallization planes for completing the memory chip are effected in the customarily known manner, as described in FIG. 3.

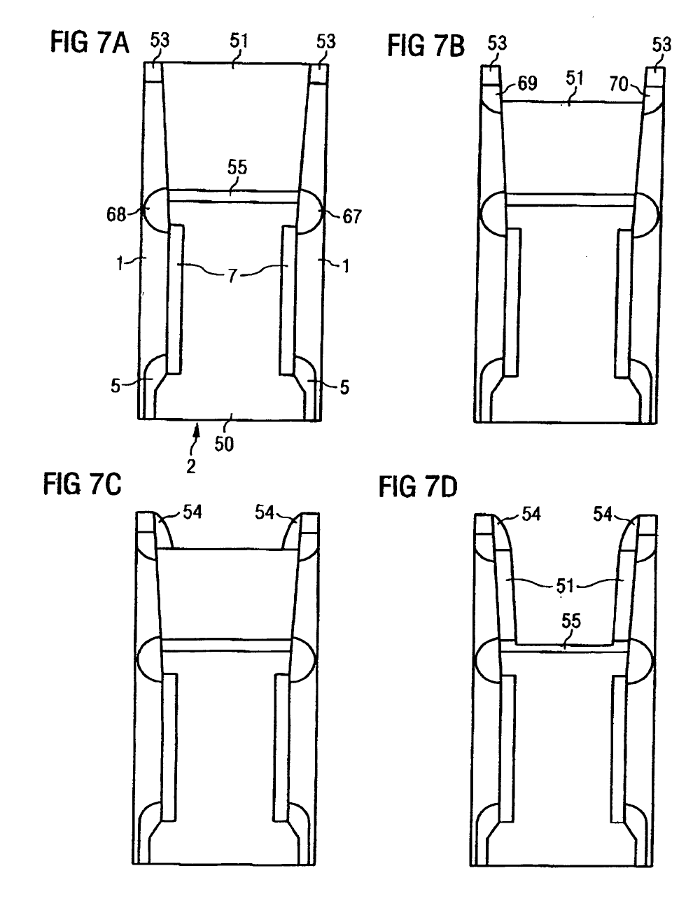

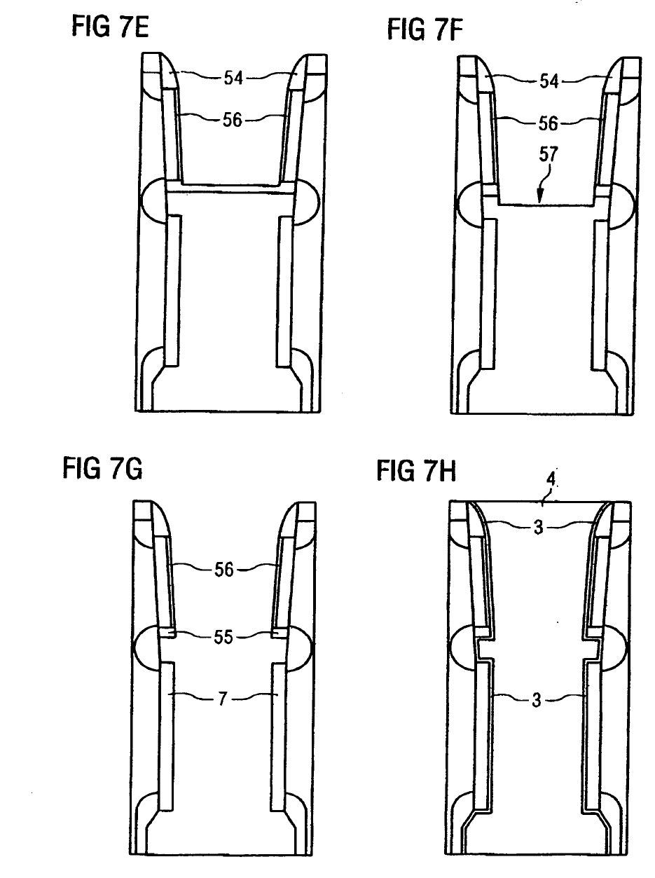

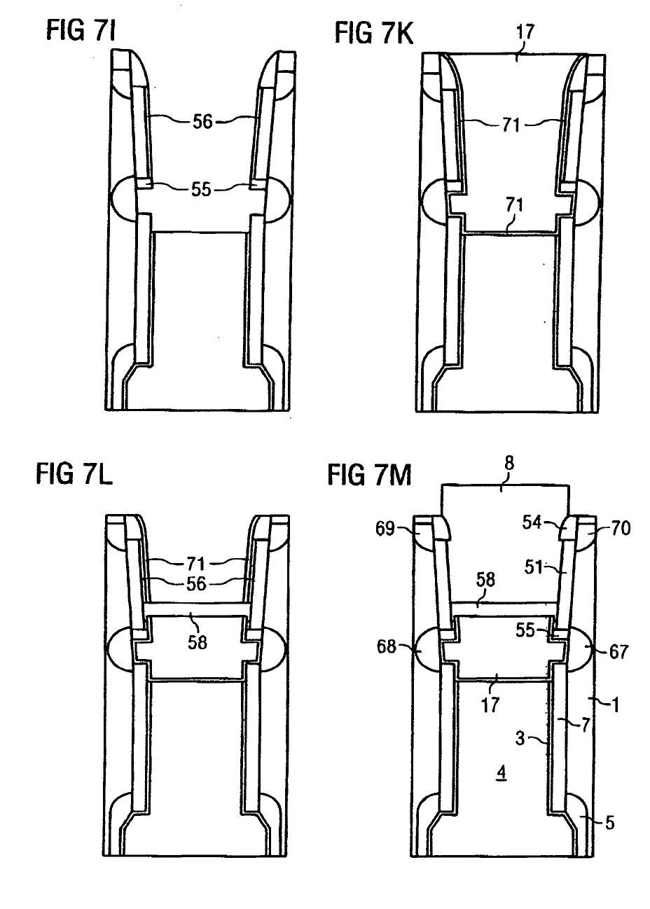

FIG. 7 shows a method for fabricating a third embodiment of a memory cell arrangement. The third embodiment has a memory cell arrangement with a vertical, double gate terminal. The memory cell arrangement is fabricated by a p-conducting silicon substrate 1 being covered with a silicon dioxide and silicon nitride layer as an etching mask. Firstly, a trench 2 is etched out from the silicon substrate 1 by means of a lithography method and an etching method using a hard mask. Afterward, the hard mask is removed and the trench 2 is subjected to a cleaning method. The walls of the trench 2 are thereupon covered locally with an arsenic-doped glass layer 31. A vertical plate doping zone 5 is introduced in the lower region of the trench 2 by means of a subsequent diffusion process. After the removal of the mask layers and cleaning of the trench 2, the trench 2 is filled with a dummy filling 32. The dummy filling 32 comprises for example a silicon dioxide and/or a silicon layer.

In an advantageous refinement of the method, the trench 2 is etched slightly bulgingly in the lower section by means of a proportionately isotropic etching method, thereby producing a negative sidewall angle. In this way, the cross section of the opening of the trench 2 decreases toward the top, so that the opening of the trench 2 is closed during the filling of the trench 2 with the dummy filling 32 before deeper regions of the trench 2 have been completely filled with the dummy filling 32. As a result, an extended shrink hole, i.e. a cavity, which makes it significantly easier for the dummy filling 50 subsequently to be stripped out again without any residues, remains in the lower section of the trench 2 along the axis of symmetry thereof. The dummy filling 50 is formed in such a way that a simple and complete stripping-out is possible by means of an etching method.

In a subsequent process step, the dummy filling 32 is etched back in planar fashion right into the upper part of the trench 2. Afterward, the uncovered regions of the oxide layer which is formed on the sidewalls of the trench 2 are removed. An insulation collar 7 is thereupon introduced in the upper region of the trench 2 by means of a conventional process implementation through multiple layer deposition processes and etching-back processes. The insulation collar 7 is preferably formed from silicon dioxide or silicon nitride. A first strap doping zone 67 is subsequently formed at opposite sides of the trench 2.

After the removal of the auxiliary layers, the upper edge of the insulation collar 7 and also the inner wall of the trench 2 are uncovered and are coated with a thin silicon dioxide layer. A first insulation plate 55 is thereupon formed by means of an anisotropic layer deposition method. The thin oxide layer on the inner wall of the trench 2 is thereupon removed again and a gate oxide layer is formed on the inner wall of the trench 2. The open, upper region of the trench 2 is then filled with a gate layer 51 and planarized as far as the silicon nitride layer 53. This method state is illustrated in FIG. 7A.

In a further process step, a horizontal plate doping zone 15 and a field insulation layer 9 are formed by means of conventional process steps. Afterward, the gate layer 51 is etched back to below the surface of the substrate 1. The uncovered side areas of the silicon substrate 1 are then doped and a third and fourth doping zone 69, 70 are fabricated, which constitute two source regions. This method state is illustrated in FIG. 7B. The first and third doping zones and the assigned gate layer 51 form a transistor. Equally, the second and fourth doping zones and the assigned dual gate 51 form a further transistor.

Afterward, a spacer 54 made of an insulating material is formed on the uncovered side areas of the silicon nitride 53. This method state is illustrated in FIG. 7C.

In a further process step, the gate layer 51 is patterned anisotropically using the spacers 54 as an etching mask and etched away down to the first insulation plate 55. This method state is illustrated in FIG. 7D. The vertical areas of the residual dual layer 51 are thereupon coated with a silicon oxide layer 56. This method state is illustrated in FIG. 7E.

In a subsequent step, the first insulation plate 55 is cut through down to the dummy filling 50 by means of an anisotropic etching method. This method state is illustrated in FIG. 7F.

The open trench 2 with the spacers 54, the vertical silicon dioxide layers 56 and the vertical sidewalls of the first insulation plate 55 form a sealed etching opening 57. The dummy filling 50 is stripped out from the trench 2 without any residues through the etching opening 57. This method state is illustrated in FIG. 7G.

During this process step, surfaces that are otherwise open on the memory chip are made sufficiently resistant to the etching solution used for stripping out the dummy filling 50 or are covered by a corresponding sealing layer.

The cleaning of the inner wall of the trench 2 is followed by the conformal deposition of the storage dielectric 3 and a trench electrode 4. The storage dielectric 3 and the trench electrode 4 are preferably deposited by means of an atomic layer deposition method (ALD). A metallic material is used for the formation of the trench electrode, as in the preceding embodiments. This method state is illustrated in FIG. 7H.

Afterward, the trench electrode 4 is selectively etched back to below the upper edge of the insulation collar 7. The etched-back trench electrode 4 is thereupon used as an etching mask for an isotropic removal of the uncovered storage dielectric 3. This method state is illustrated in FIG. 7J.

Afterward, the free surfaces are coated with a protective layer 71 made of nitride and the strap filling 17 is deposited. This method state is illustrated in FIG. 7K.

Afterward, the strap filling 17 is etched back in planar fashion down to a level arranged just above the first insulation plate 55. A second insulation plate 58 is then formed on the strap filling. This method state is illustrated in FIG. 7L.

The second protective layer 71 is subsequently removed from the surface of the trench 2. In a further method step, the silicon oxide layer 56 is removed from the gate layer 51. A word line 8 is subsequently deposited and patterned. This method state is illustrated in FIG. 7M. The further processing of the bit line contacts, the bit line and subsequent metallization planes through to the completion of the memory chip is effected in a conventional manner.

The formation of the storage dielectric 3 and the trench electrode 4 in the exemplary embodiments of FIGS. 4, 5, 6, 7 is to be chosen in accordance with the exemplary embodiment of FIG. 1.

On the basis of the methods described, the trench capacitors can be provided with a trench filling which does not withstand the temperatures used during the fabrication of the transistors without a reduction of its material parameters.

1. A memory chip comprising a substrate, into which memory cells are introduced,
the memory cells having a trench capacitor and a transistor,
the trench capacitor at least partially having a filling, and
the transistor having a source terminal, a drain terminal and a gate terminal
the drain terminal being electrically conductively connected to the trench capacitor, wherein
the filling at least partially has a material which is unstable at high temperatures, which occur during a high-temperature process during fabrication of the memory chip, the filling being introduced after the high-temperature processes, and the filling was not exposed to a high-temperature process.

2. The memory chip as claimed in claim 1, wherein the filling has at least one of the materials from the following group: hafnium oxide, zirconium oxide, lanthanum oxide, yttrium oxide, and strontium titanium oxide.

3. The memory chip as claimed in claim 2, wherein the filling has a silicate compound.

4. The memory chip as claimed in claim 1, wherein the filling at least partially has a metallic material.

5. The memory chip as claimed in claim 1, wherein a wall of the trench is at least partially covered with a dielectric layer,
a metallic layer is at least partially applied on the dielectric layer,
the metallic layer is electrically conductively connected to the drain terminal of the transistor via a strap filling.

6. The memory chip as claimed in claim 1, wherein an electrically conductive layer is formed in a manner adjoining the trench in the substrate.

7. The memory chip as claimed in claim 1, wherein the trench is covered by an epitaxial layer,
an opening is introduced in the epitaxial layer,
a conductive connection between the filling and the drain terminal is formed through the opening,
a dielectric layer is at least partially applied on a side of the epitaxial layer which faces the trench.

8. A method for fabricating a memory cell having a trench capacitor, comprising:
introducing a trench into a substrate;
filling the trench at least partially with a dummy filling;
applying a covering layer to the substrate, which covering layer is formed as an epitaxial layer;
introducing a transistor into the covering layer;
removing the dummy filling from the trench;
introducing a storage dielectric and a trench electrode into the trench, a trench capacitor being created, and
forming a connection of the trench electrode to a terminal of the transistor.

9. The method as claimed in claim 8, wherein a channel is etched into the covering layer as far as the dummy filling,
the dummy filling is etched out via the channel,
a dielectric layer is at least partially applied to the wall of the trench,
a conductive layer is applied to the dielectric layer, and
the conductive layer is electrically conductively connected to a terminal of the transistor.

10. The method as claimed in claim 8, wherein, after the etching of the channel, sidewalls of the channel are covered with a protective layer made of nitride, and
the dummy filling is subsequently etched out from the trench.
